(19) United States
(12) Patent Application Publication
(10) Pub. No.: US 2026/0305489 A1
(43) Pub. Date: Oct. 1, 2026

(54) SEMICONDUCTOR MODULE ARRANGEMENT

(71) Applicant: Infineon Technologies AG, Neubiberg (DE)

(72) Inventors: Georg Troska, Fröndenberg (DE); Matthias Bürger, Bad Wünnenberg (DE)

(21) Appl. No.: 19/573,023

(22) Filed: Mar. 20, 2026

(30) Foreign Application Priority Data
Mar. 28, 2025 (DE) 102025112111.7

(51) Int. Cl. H10W 90/10; H10W 70/60; H10W 70/652; H10W 70/655; H10W 76/12; H10W 90/00

(52) U.S. Cl. CPC H10W 90/10; H10W 70/611; H10W 70/652; H10W 70/655; H10W 76/165; H10W 90/401; H10W 90/754; H10W 90/734

(57) ABSTRACT

A semiconductor module arrangement includes: a housing having a first lateral side, a second lateral side opposite the first lateral side, a third lateral side perpendicular to the first lateral side and the second lateral side, and a fourth lateral side opposite the third lateral side; a first and a second substrate arranged in the housing such that the first substrate is between the second substrate and the third lateral side; a first semiconductor element on the first substrate; and a second semiconductor element on the second substrate. The semiconductor module arrangement further includes a first supply terminal, a second supply terminal and one or more output terminals arranged in a third section of the housing between the third lateral side and the fourth lateral side. A distance between the third section and the third lateral side essentially equals a distance between the third section and the fourth lateral side.

### TECHNICAL FIELD

The instant disclosure relates to a semiconductor module arrangement.

### BACKGROUND

Semiconductor module arrangements often include at least one substrate arranged in a housing. A semiconductor arrangement including a plurality of controllable semiconductor elements (e.g., two IGBTs in a half-bridge configuration) is arranged on each substrate of the at least one substrate. Each substrate usually comprises a substrate layer (e.g., a ceramic layer), a first metallization layer deposited on a first side of the substrate layer and (optionally) a second metallization layer deposited on a second side of the substrate layer. The controllable semiconductor elements are mounted, for example, on the first metallization layer. The second metallization layer may optionally be attached to a base plate. The controllable semiconductor devices are usually mounted to the substrate by soldering or sintering techniques. Electrical lines or electrical connections are used to connect different semiconductor devices of the semiconductor arrangement with each other. Further, terminal elements are provided to contact the semiconductor arrangement from outside the housing. Such terminal elements are usually electrically coupled to the first metallization layer with a first end. A second end of the terminal elements protrudes out of the housing. The layout of the semiconductor module arrangement, in particular the positioning of the terminal elements, may have an impact on the switching characteristics, the stray inductance and the losses of the semiconductor arrangement.

There is a need for a semiconductor module arrangement with improved switching characteristics and reduced stray inductance.

### SUMMARY

A semiconductor module arrangement includes a housing including a first lateral side, a second lateral side opposite the first lateral side, a third lateral side perpendicular to the first lateral side and the second lateral side, and a fourth lateral side opposite the third lateral side, a first substrate and a second substrate arranged in the housing such that the first substrate is arranged between the second substrate and the third lateral side, each of the first and second substrate including a dielectric insulation layer and a first metallization layer arranged on a surface of the dielectric insulation layer, wherein the first metallization layer includes a first section, and a second section, and a first semiconductor element arranged on the first substrate, and a second semiconductor element arranged on the second substrate, wherein each of the first and second semiconductor element includes a first contact pad, and a second contact pad, wherein the second contact pad of the first semiconductor element is electrically coupled to the first section of the first substrate, and the second contact pad of the second semiconductor element is electrically coupled to the first section of the second substrate, the first contact pad of the first semiconductor element is electrically coupled to the second section of the first substrate, and the first contact pad of the second semiconductor element is electrically coupled to the second section of the second substrate, the semiconductor module arrangement further includes a first supply terminal electrically coupled to the first section of the first substrate, a second supply terminal electrically coupled to the second section of the second substrate, and one or more output terminals electrically coupled to the second section of the first substrate and the first section of the second substrate, wherein the first supply terminal, the second supply terminal, and the one or more output terminals are arranged in a third section of the housing arranged between the third lateral side and the fourth lateral side, wherein a distance between the third section of the housing and the third lateral side essentially equals a distance between the third section of the housing and the fourth lateral side.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module arrangement.

FIG. 2 schematically illustrates a circuit arrangement according to one example.

FIG. 3 schematically illustrates a top view of a semiconductor module arrangement according to embodiments of the disclosure.

FIG. 4 schematically illustrates a top view of a semiconductor module arrangement according to further embodiments of the disclosure.

FIG. 5 schematically illustrates a top view of a semiconductor module arrangement according to further embodiments of the disclosure.

FIG. 6 schematically illustrates a top view of a semiconductor module arrangement according to even further embodiments of the disclosure.

FIG. 7 schematically illustrates a top view of a semiconductor module arrangement according to even further embodiments of the disclosure.

FIG. 8 schematically illustrates a top view of a semiconductor module arrangement according to even further embodiments of the disclosure.

FIG. 9 schematically illustrates a top view of a semiconductor module arrangement according to even further embodiments of the disclosure.

FIG. 10 schematically illustrates a top view of a semiconductor module arrangement according to even further embodiments of the disclosure.

FIG. 11 schematically illustrates a three-dimensional view of a housing of a semiconductor module arrangement according to embodiments of the disclosure.

FIG. 12 schematically illustrates a three-dimensional view of a housing of a semiconductor module arrangement according to further embodiments of the disclosure.

FIG. 13 schematically illustrates a three-dimensional view of a housing of a semiconductor module arrangement according to even further embodiments of the disclosure.

FIG. 14 schematically illustrates a three-dimensional view of a housing of a semiconductor module arrangement according to even further embodiments of the disclosure.

FIG. 15 schematically illustrates a three-dimensional view of a housing of a semiconductor module arrangement according to even further embodiments of the disclosure.

FIG. 16 schematically illustrates a three-dimensional view of a housing of a semiconductor module arrangement according to even further embodiments of the disclosure.

FIG. 17 schematically illustrates a three-dimensional view of a semiconductor module arrangement according to even further embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

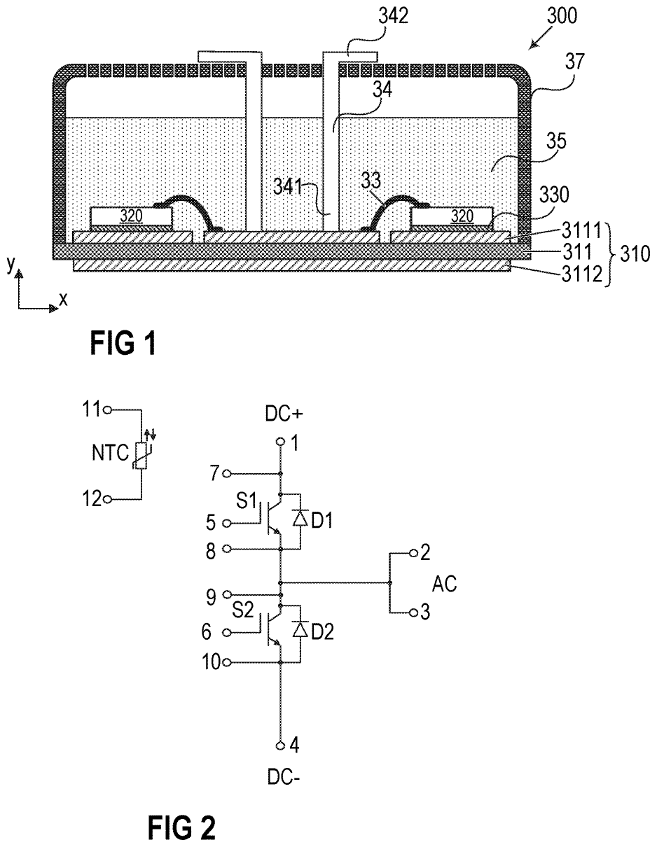

Referring to FIG. 1, a cross-sectional view of a semiconductor module arrangement 300 is schematically illustrated. The semiconductor module arrangement 300 includes a housing 37 and a substrate 310. The substrate 310 includes a dielectric insulation layer 311, a (structured) first metallization layer 3111 attached to the dielectric insulation layer 311, and a (structured) second metallization layer 3112 attached to the dielectric insulation layer 311. The dielectric insulation layer 311 is disposed between the first and second metallization layers 3111, 3112.

Each of the first and second metallization layers 3111, 3112 may consist of or include one of the following materials: copper; a copper alloy; aluminum; an aluminum alloy; any other metal or alloy that remains solid during the operation of the power semiconductor module arrangement. The substrate 310 may be a ceramic substrate, that is, a substrate in which the dielectric insulation layer 311 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 310 may, e.g., be a Direct Copper Bonding (DCB) substrate, a Direct Aluminum Bonding (DAB) substrate, or an Active Metal Brazing (AMB) substrate. Further, the substrate 310 may be an Insulated Metal Substrate (IMS). An Insulated Metal Substrate generally comprises a dielectric insulation layer 311 comprising (filled) materials such as epoxy resin or polyimide, for example. The material of the dielectric insulation layer 311 may be filled with ceramic particles, for example. Such particles may comprise, e.g., SiO₂, Al₂O₃, AlN, or BN and may have a diameter of between about 1 μm and about 50 μm. The substrate 310 may also be a conventional printed circuit board (PCB) having a non-ceramic dielectric insulation layer 311. For instance, a non-ceramic dielectric insulation layer 311 may consist of or include a cured resin.

The substrate 310 is arranged in a housing 37. In the example illustrated in FIG. 1, the substrate 310 forms a base surface of the housing 37, while the housing 37 itself solely comprises sidewalls and a cover. This, however, is only an example. It is also possible that the housing 37 further comprises a base surface and the substrate 310 be arranged on the base surface and inside the housing 37. According to another example, the substrate 310 may be mounted on a base plate (not specifically illustrated). In some semiconductor module arrangements 300, more than one substrate 310 is arranged on the base surface of a housing 37 or on a single base plate (not illustrated). The base plate may form a base surface of the housing 37, for example.

One or more semiconductor bodies 320 may be arranged on the at least one substrate 310. Each of the semiconductor bodies 320 arranged on the at least one semiconductor substrate 310 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable semiconductor element.

The one or more semiconductor bodies 320 may form a semiconductor arrangement on the substrate 310. In FIG. 1, only two semiconductor bodies 320 are exemplarily illustrated. The second metallization layer 3112 of the substrate 310 in FIG. 1 is a continuous layer. The first metallization layer 3111 is a structured layer in the example illustrated in FIG. 1. “Structured layer” means that the first metallization layer 3111 is not a continuous layer, but includes recesses between different sections of the layer. Such recesses are schematically illustrated in FIG. 1. The first metallization layer 3111 in this example includes three different sections. This, however, is only an example. Any other number of sections is generally possible. Different semiconductor bodies 320 may be mounted to the same or to different sections of the first metallization layer 3111. Different sections of the first metallization layer 3111 may have no electrical connection or may be electrically connected to one or more other sections using, e.g., bonding wires 33. Electrical connections 33 may also include bonding ribbons, connection plates or conductor rails, for example, to name just a few examples. The one or more semiconductor bodies 320 may be electrically and mechanically connected to the substrate 310 by an electrically conductive connection layer 330. Such an electrically conductive connection layer may be a solder layer, a layer of an electrically conductive adhesive, or a layer of a sintered metal powder, e.g., a sintered silver powder, for example.

According to other examples, it is also possible that the second metallization layer 3112 is a structured layer. It is further possible to omit the second metallization layer 3112 altogether.

The semiconductor module arrangement 300 illustrated in FIG. 1 further includes terminal elements 34. The terminal elements 34 are electrically connected to the first metallization layer 3111 and provide an electrical connection between the inside and the outside of the housing 37. The terminal elements 34 may be electrically connected to the first metallization layer 3111 with a first end 341, while a second end 342 of the terminal elements 34 protrudes out of the housing 37. The terminal elements 34 may be electrically contacted from the outside at their second end 342. A first part of the terminal elements 34 may extend through the inside of the housing 37 in an essentially vertical direction y. The vertical direction y is a direction perpendicular to a top surface of the substrate 310, wherein the top surface of the substrate 310 is a surface on which the at least one semiconductor body 320 is mounted. The second ends 342 of the terminal elements 34 may be bent such that they extend in a first horizontal direction x which is parallel to the top surface of the substrate 310. In this way, for some applications it may be easier to electrically contact the second ends 342. The terminal elements 34 illustrated in FIG. 1, however, are only examples. Terminal elements 34 may be implemented in any other way and may be arranged anywhere within the housing 37. For example, one or more terminal elements 34 may be arranged close to or adjacent to the sidewalls of the housing 37. It is also possible that the second ends 342 completely extend in the vertical direction y instead of being bent in the first horizontal direction x. Any other suitable implementation is possible.

The semiconductor bodies 320 each may include a chip pad metallization (not specifically illustrated), e.g., a source, drain, anode, cathode or gate metallization. A chip pad metallization generally provides a contact surface for electrically connecting the semiconductor body 320. The chip pad metallization may electrically contact a connection layer 330, a terminal element 34, or an electrical connection 33, for example. A chip pad metallization may consist of or include a metal such as aluminum, copper, gold or silver, for example. The electrical connections 33 and the terminal elements 34 may also consist of or include a metal such as copper, aluminum, gold, or silver, for example.

Now referring to FIG. 2, the at least two semiconductor bodies 320 may be arranged in a half-bridge configuration, for example. FIG. 2 is a circuit diagram of an exemplary half-bridge arrangement. The half-bridge arrangement is configured to convert a DC voltage into an AC voltage. The AC voltage may be provided to, e.g., a load (not illustrated). The half-bridge arrangement is coupled between a first supply node which is configured to be operatively coupled to a first electrical potential DC+ and a second supply node which is configured to be operatively coupled to a second electrical potential DC−. The first electrical potential DC+ may be a positive potential and the second electrical potential DC− may be a negative potential to supply a DC voltage via the first and second supply nodes. The first and second supply nodes form the input of the half-bridge arrangement.

The half-bridge may include one high-side switch S1 (first switch) and one low-side switch S2 (second switch) coupled in series to each other between the first supply node and the second supply node. The half-bridge arrangement may be configured to drive a load (not specifically illustrated) at an output node of the half-bridge arrangement. The load may be an inductive load, for example. The output node is electrically connected to a common node between the high-side switch S1 and the low-side switch S2.

In the circuit arrangement of FIG. 2, each switch S1, S2 of the half-bridge arrangement is implemented as an IGBT (insulated-gate bipolar transistor). This, however, is only an example. The switches S1, S2 may also be implemented as MOSFETs (Metal Oxide Semiconductor Field-Effect Transistor), JFETs (Junction Field Effect Transistor), HEMTs (High Electron Mobility Transistor), BJTs (Bipolar Junction Transistor), or any other kind of controllable semiconductor element, for example. Each of the switches S1, S2 may comprise an internal or external freewheeling diode D1, D2. According to another example, each of the switches S1, S2 comprises two or more separate switching elements electrically coupled in parallel to each other (not specifically illustrated).

Each of the first switch S1 and the second switch S2 includes a control electrode and a controllable load path between a first load electrode and a second load electrode. The load paths of the first switch S1 and the second switch S2 are coupled in series and between the first supply node and the second supply node.

Several different connection terminals may be provided in order to electrically contact the half-bridge arrangement according to the example of FIG. 2. According to one example, a first supply terminal 1 may be electrically coupled to the first supply node, and a second supply terminal 4 may be electrically coupled to the second supply node. A first control terminal 5 may be electrically coupled to the control electrode of the first switch S1, and a second control terminal 6 may be electrically coupled to the control electrode of the second switch S2. A first auxiliary emitter terminal 8 may be electrically coupled to the second load electrode of the first switch S1, and a second auxiliary emitter terminal 10 may be electrically coupled to the second load electrode of the second switch S1. A first collector terminal 7 may be electrically coupled to the first load electrode of the first switch S1, and a second collector terminal 9 may be electrically coupled to the first load electrode of the second switch S2. One or more output terminals 2, 3 may be electrically coupled to the output node of the half-bridge arrangement.

Auxiliary emitter terminals 8, 10 may be provided, e.g., in order to minimize potentially negative feedback effects on the gate-emitter voltage (gate-emitter voltage=voltage between control electrode and corresponding emitter terminal (second load electrode) of a switch S1, S2). According to another example, the auxiliary emitter terminals 8, 10 may be provided in order to detect an internal voltage drop between an emitter terminal and a respective one of the auxiliary emitter terminals 8, 10. A voltage drop may occur, for example, due to a stray inductance in the moment of switching the corresponding first or second switch S1, S2 on or off. The detected voltage drop may be used for error detection, for example.

Optionally, the arrangement may further comprise a temperature sensor such as, e.g., a Negative Temperature Coefficient Thermistor (NTC), comprising an input electrode and an output electrode. The temperature sensor may be configured to measure a temperature of the semiconductor module arrangement 300. The temperature sensor may be arranged at any suitable position in the arrangement. A first measuring terminal 11 may be electrically coupled to the input electrode, and a second measuring terminal 12 may be electrically coupled to the output electrode of the NTC.

In this way, a plurality of terminals may be provided for electrically contacting a single half-bridge arrangement. In a semiconductor module arrangement 300, each of the individual terminals 1-10, or 1-12, may be implemented as a terminal element 34, as has been described with respect to FIG. 1 above. One or more terminals may be electrically coupled to the same section of the first metallization layer 311. For example, two or more terminals that are electrically coupled to the same electrical potential may be electrically coupled to the same section of the first metallization layer 311. This, however, is only an example. It is also possible that two or more terminals that are electrically coupled to the same electrical potential are electrically coupled to two or more different sections of the first metallization layer 311. Such sections may be electrically coupled to each other by means of bonding wires, connection plates or conductor rails, for example.

The layout of the semiconductor module arrangement, and in particular the position of the terminal elements 34 within the housing 37 may have an influence with regard to the switching behavior of the semiconductor arrangement. Therefore, the positions of the individual terminal elements 34 within the housing 37 may be chosen to comply with requirements concerning creepage distances and to improve the switching behavior of the half-bridge arrangement.

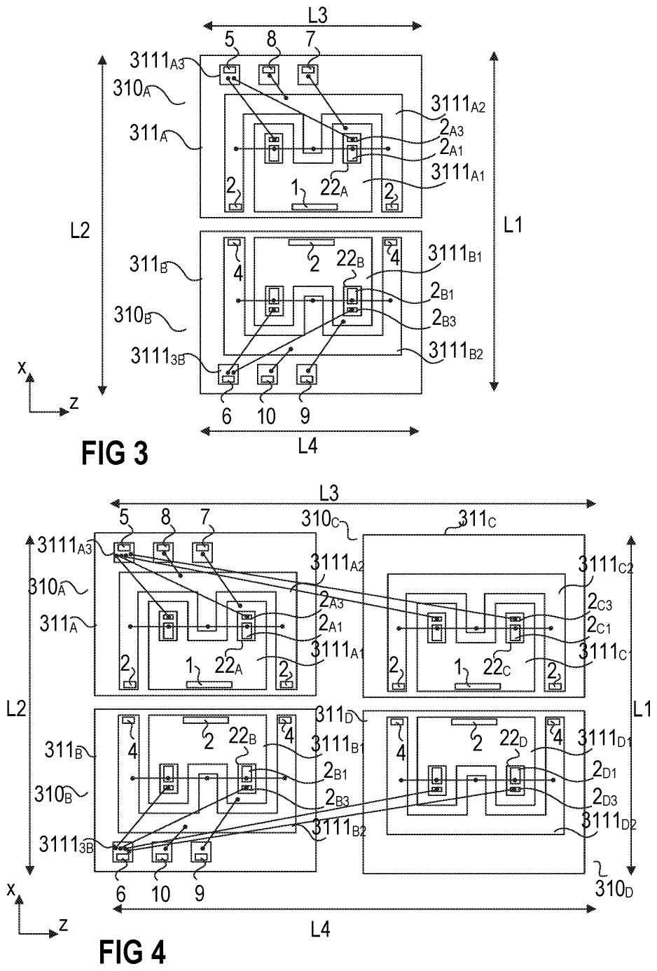

Now referring to FIG. 3, a semiconductor module arrangement according to embodiments of the disclosure is schematically illustrated. The semiconductor module arrangement comprises a housing 37 comprising a first lateral side L1, a second lateral side L2 opposite the first lateral side L1, a third lateral side L3 perpendicular to the first lateral side L1 and the second lateral side L2, and a fourth lateral side L4 opposite the third lateral side L3. In FIG. 3, the housing 37 is not specifically illustrated. The lateral sides L1, L2, L3, L4 are indicated by means of arrows in FIG. 3. The semiconductor module arrangement further comprises a first substrate 310_{A} and a second substrate 310_{B} arranged in the housing 37 such that the first substrate 310_{A} is arranged between the second substrate 310_{B} and the third lateral side L3, each of the first and second substrate 310_{A}, 310_{B} comprising a dielectric insulation layer 311_{A}, 311_{B} and a first metallization layer 3111_{A}, 3111_{B} arranged on a surface of the dielectric insulation layer 311_{A}, 311_{B}, wherein the first metallization layer 3111_{A}, 3111_{B} comprises a first section 3111_{A1}, 3111_{B1}, a second section 3111_{A2}, 3111_{B2}, and a third section 3111_{A3}, 3111_{B3}. The semiconductor module arrangement further comprises a first controllable semiconductor element 22_{A} arranged on the first substrate 310_{A}, and a second controllable semiconductor element 22_{B} arranged on the second substrate 310_{B}, wherein each of the first and second controllable semiconductor elements 22_{A}, 22_{B} comprises a first contact pad 2x₁, a second contact pad, and a third contact pad 2x₃. The first controllable semiconductor element 22_{A} may form the first switch S1 as illustrated in FIG. 2, and the second controllable semiconductor element 22_{B} may form the second switch S2. As has been described above, each of the first switch S1 and second switch S2 may be formed by one or more controllable semiconductor elements 22 coupled in parallel to each other. FIG. 3 schematically illustrates two controllable semiconductor elements 22 arranged on the first substrate 310_{A} and forming the first switch S1, and two controllable semiconductor elements 22 arranged on the second substrate 310_{B} and forming the second switch S2.

Still referring to FIG. 3, the second contact pad of the first controllable semiconductor element 22_{A} is electrically coupled to the first section 3111_{A1} of the first substrate 310_{A}, and the second contact pad of the second controllable semiconductor element 22_{B} is electrically coupled to the first section 3111_{B1} of the second substrate 310_{B}. The first contact pad 2_{A1} of the first controllable semiconductor element 22_{A} is electrically coupled to the second section 3111_{A2} of the first substrate 310_{A}, and the first contact pad 2_{B1} of the second controllable semiconductor element 22_{B} is electrically coupled to the second section 3111_{B2} of the second substrate 310_{B}. The third contact pad 2_{A3} of the first controllable semiconductor element 22_{A} is electrically coupled to the third section 3111_{A3} of the first substrate 310_{A}, and the third contact pad 2_{B3} of the second controllable semiconductor element 22_{B} is electrically coupled to the third section 3111_{B3} of the second substrate 310_{B}.

In the arrangement illustrated in FIG. 3, the controllable semiconductor elements 22_{A}, 22_{B} are implemented as so-called vertical devices, and the second contact pads of the two controllable semiconductor elements 22_{A}, 22_{B} are electrically coupled to the respective first sections 3111_{A1}, 3111_{B1} by means of electrically conductive connection layers and are therefore not visible in the top view of FIG. 3. Implementing the controllable semiconductor elements 22_{A}, 22_{B} as vertical devices, however, is only an example. Instead, the devices may also be implemented as so-called lateral devices. In lateral devices, all contact pads are arranged on a surface of the respective device that faces away from the respective substrate 310. If the controllable semiconductor elements 22_{A}, 22_{B} are implemented as lateral devices, the second contact pads of the two controllable semiconductor elements 22_{A}, 22_{B} may be electrically coupled to the respective first sections 3111_{A1}, 3111_{B1} by means of one or more electrical connection elements 33 (e.g., bonding wires), for example.

Still referring to FIG. 3, the semiconductor module arrangement 300 further comprises a first control terminal 5 electrically coupled to the third section 3111_{A3} of the first substrate 310_{A}, a first auxiliary emitter terminal 8 electrically coupled to the second section 3111_{A2} of the first substrate 310_{A}, and a first collector terminal 7 electrically coupled to the first section 3111_{A1} of the first substrate 310_{A}, wherein the first control terminal 5, the first auxiliary emitter terminal 8, and the first collector terminal 7 are arranged in a first section of the housing 37 adjacent to the third lateral side L3. The first collector terminal 7 and the first auxiliary emitter terminal 8 may be arranged on additional sections of the first substrate 310_{A}, for example. Electrical connections to the first section 3111_{A1}, and the second section 3111_{A2} of the first substrate 310_{A} may be implemented by means of electrical connection elements 33, for example. Other implementations, however, are also possible. For example, alternatively the first collector terminal 7 and the first auxiliary emitter terminal 8 may be arranged directly on the first section 3111_{A1}, and the second section 3111_{A2}, respectively. The semiconductor module arrangement 300 further comprises a second control terminal 6 electrically coupled to the third section 3111_{B3} of the second substrate 310_{B}, a second auxiliary emitter terminal 10 electrically coupled to the second section 3111_{B2} of the second substrate 310_{B}, and a second collector terminal 9 electrically coupled to the first section 3111_{B1} of the second substrate 310_{B}, wherein the second control terminal 6, the second auxiliary emitter terminal 10, and the second collector terminal 9 are arranged in a second section of the housing 37 adjacent to the fourth lateral side L4. The second collector terminal 9 and the second auxiliary emitter terminal 10 may be arranged on additional sections of the second substrate 310_{B}, for example. Electrical connections to the first section 3111_{B1}, and the second section 3111_{B2} of the second substrate 310_{B} may be implemented by means of electrical connection elements 33, for example. Other implementations, however, are also possible. For example, alternatively the second collector terminal 9 and the second auxiliary emitter terminal 10 may be arranged directly on the first section 3111_{B1}, and the second section 3111_{B2}, respectively. The semiconductor module arrangement 300 further comprises a first supply terminal 1 electrically coupled to the first section 3111_{A1} of the first substrate 310_{A}, a second supply terminal 4 electrically coupled to the second section 3111_{B2} of the second substrate 310_{B}, and one or more output terminals 2, 3 electrically coupled to the second section 3111_{A2} of the first substrate 310_{A} and the first section 3111_{B1} of the second substrate 310_{B}, wherein the first supply terminal 1, the second supply terminal 4, and the one or more output terminals 2, 3 are arranged in a third section of the housing 37 arranged between the first section and the second section.

That is, the main terminals 1, 2, 3, 4 or power terminals of both substrates 310_{A}, 310_{B} which carry significant currents and voltages are grouped together, any auxiliary terminals and control terminals 5, 7, 8 of the first substrate 310_{A} are grouped together, and any auxiliary terminals and control terminals 6, 9, 10 of the second substrate 310_{B} are grouped together, with the main terminals 1, 2, 3, 4 being arranged between the auxiliary terminals and control terminals 5, 7, 8 of the first substrate 310_{A}, and the auxiliary terminals and control terminals 6, 9, 10 of the second substrate 310_{B}.

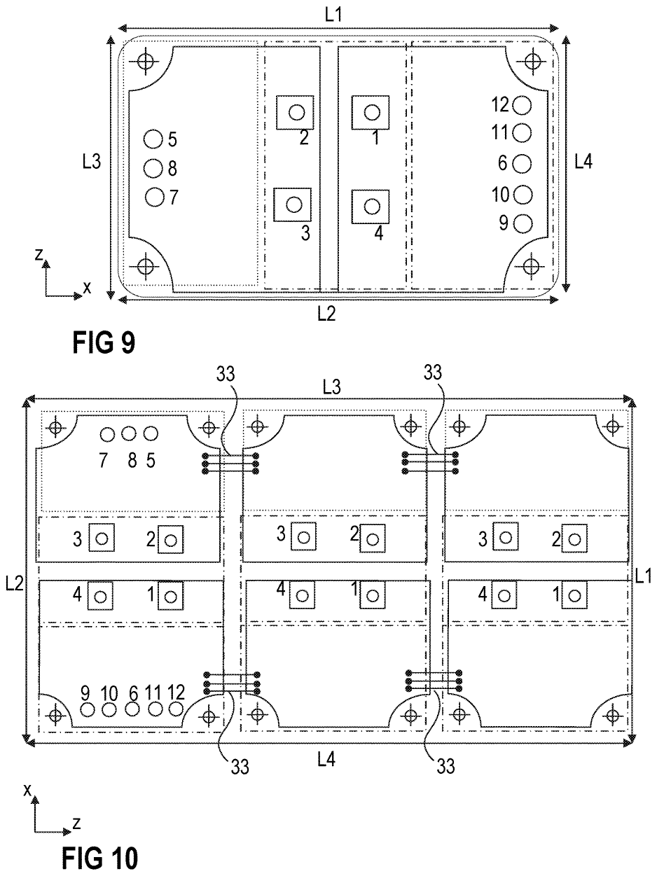

This is also schematically illustrated in FIG. 9, which illustrates a top view of a housing 37 of a semiconductor module arrangement 300, with the second ends of the terminals 1-10 protruding out of the housing 37. In the arrangement of FIG. 9, second ends of a first measuring terminal 11 and a second measuring terminal 12 are also illustrated. The first and second measuring terminals 11, 12 may be grouped together with the auxiliary terminals and control terminals 6, 9, 10 of the second substrate 310_{B}, or with the auxiliary terminals and control terminals 5, 7, 8 of the first substrate 310_{A}, for example.

According to some embodiments, and as is exemplarily illustrated in FIG. 9, the first control terminal 5 (e.g., at least the second end of the first control terminal 5), the first auxiliary emitter terminal 8 (e.g., at least the second end of the first auxiliary emitter terminal 8), and the first collector terminal 7 (e.g., at least the second end of the first collector terminal 7) may be arranged in one row and in parallel to the third lateral side L3. Similarly, the second control terminal 6 (e.g., at least the second end of the second control terminal 6), the second auxiliary emitter terminal 10 (e.g., at least the second end of the second auxiliary emitter terminal 10), and the second collector terminal 9 (e.g., at least the second end of the second collector terminal 9) may be arranged in one row and in parallel to the fourth lateral side L4.

According to alternative embodiments, the first control terminal 5 (e.g., at least the second end of the first control terminal 5), the first auxiliary emitter terminal 8 (e.g., at least the second end of the first auxiliary emitter terminal 8), and the first collector terminal 7 (e.g., at least the second end of the first collector terminal 7) may be arranged in one row and in parallel to the first lateral side L1. Similarly, the second control terminal 6 (e.g., at least the second end of the second control terminal 6), the second auxiliary emitter terminal 10 (e.g., at least the second end of the second auxiliary emitter terminal 10), and the second collector terminal 9 (e.g., at least the second end of the second collector terminal 9) may be arranged in one row and in parallel to the first lateral side L1. According to some embodiments, it is even possible that the first control terminal 5 (e.g., at least the second end of the first control terminal 5), the first auxiliary emitter terminal 8 (e.g., at least the second end of the first auxiliary emitter terminal 8), the first collector terminal 7 (e.g., at least the second end of the first collector terminal 7), the second control terminal 6 (e.g., at least the second end of the second control terminal 6), the second auxiliary emitter terminal 10 (e.g., at least the second end of the second auxiliary emitter terminal 10), and the second collector terminal 9 (e.g., at least the second end of the second collector terminal 9) are all arranged in one and the same row and in parallel to, e.g., the third lateral side L3 (see, e.g., FIG. 15). Generally, the respective terminals may be arranged in any way with the respective section of the housing 37.

According to some embodiments, and as is schematically illustrated in FIG. 9, the semiconductor module arrangement 300 comprises two output terminals 2, 3, wherein a second end of the first supply terminal 1 arranged outside of the housing 37, and a second end of the second supply terminal 4 arranged outside of the housing 37 are arranged in one row and in parallel to the third and fourth lateral sides L3, L4, second ends of the two output terminals 2, 3 arranged outside of the housing 37 are arranged in one row and in parallel to the third and fourth lateral sides L3, L4, and the second end of the first supply terminal 1 and the second end of the second supply terminal 4 are arranged between the second ends of the two output terminals 2, 3 and the fourth lateral side L4. Alternatively, the second end of the first supply terminal 1 and the second end of the second supply terminal 4 may be arranged between the second ends of the two output terminals 2, 3 and the third lateral side L3, for example.

According to an alternative embodiment, the semiconductor module arrangement 300 comprises only one output terminal 2, wherein a second end of the first supply terminal 1 arranged outside of the housing 37, a second end of the second supply terminal 4 arranged outside of the housing 37, and a second end of the output terminal 2 arranged outside of the housing 37 are arranged in one row and in parallel to the first and second lateral sides L1, L2. This is schematically illustrated in FIGS. 12, 13 and 14.

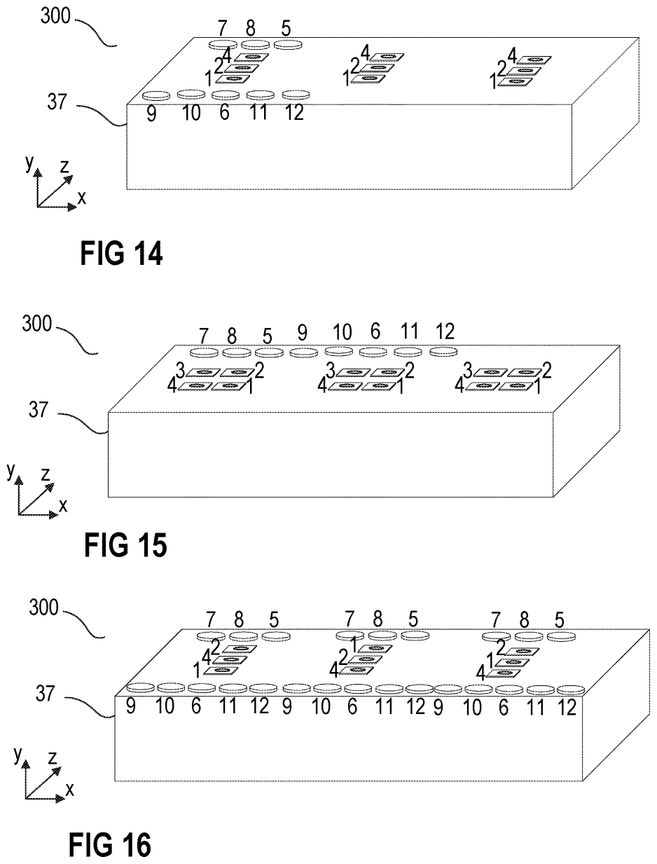

According to some embodiments, the second end of the second supply terminal 4 may be arranged between the second end of the output terminal 2 and the second end of the first supply terminal 1 (see, e.g., FIG. 12). According to alternative embodiments, the second end of the first supply terminal 1 may be arranged between the second end of the second supply terminal 4 and the second end of the output terminal 2 (see, e.g., FIG. 13). According to further alternative embodiments, the second end of the output terminal 2 may be arranged between the second end of the first supply terminal 1 and the second end of the second supply terminal 4 (see, e.g., FIG. 14).

The semiconductor module arrangement may comprise a single half-bridge, as schematically illustrated in FIGS. 3 and 9, for example. It is, however, also possible that the semiconductor module arrangement comprises two or even more than two half-bridges. That is, according to some embodiments, and as is schematically illustrated in FIG. 4, the semiconductor module arrangement 300 may further comprise a third substrate 310_{C} and a fourth substrate 310_{D} arranged in the housing 37 such that the third substrate 310_{C} is arranged between the fourth substrate 310_{D} and the third lateral side L3 and between the first substrate 310_{A} and the first lateral side L1, and the fourth substrate 310_{D} is arranged between the second substrate 310_{B} and the first lateral side L1, each of the third and fourth substrate 310_{C}, 310_{D} comprising a dielectric insulation layer 311_{C}, 311_{D} and a first metallization layer 3111_{C}, 3111_{D} arranged on a surface of the dielectric insulation layer 311_{C}, 311_{D}, wherein the first metallization layer 3111_{C}, 3111_{D} comprises a first section 3111_{C1}, 3111_{D1}, a second section 3111_{C2}, 3111_{D2}, and a third section 3111_{C3}, 3111_{D3}. The semiconductor module arrangement may further comprise a third controllable semiconductor element 22_{C} arranged on the third substrate 310_{C}, and a fourth controllable semiconductor element 22_{D} arranged on the fourth substrate 310_{D}, wherein each of the third and fourth controllable semiconductor elements 22_{C}, 22_{D} comprises a first contact pad 2x₁, a second contact pad, and a third contact pad 2x₃.

The second contact pad of the third controllable semiconductor element 22_{C} is electrically coupled to the first section 3111_{C1} of the third substrate 310_{C}, and the second contact pad of the fourth controllable semiconductor element 22_{D} is electrically coupled to the first section 3111_{D1} of the fourth substrate 310_{D}. The first contact pad 2_{C1} of the third controllable semiconductor element 22_{C} is electrically coupled to the second section 3111_{C2} of the third substrate 310_{C}, and the first contact pad 2_{D1} of the fourth controllable semiconductor element 22_{D} is electrically coupled to the second section 3111_{D2} of the fourth substrate 310_{D}.

The semiconductor module arrangement 300 further comprises an additional first supply terminal 1 electrically coupled to the first section 3111_{C1} of the third substrate 310_{C}, an additional second supply terminal 4 electrically coupled to the second section 3111_{D2} of the fourth substrate 310_{D}, and one or more additional output terminals 2, 3 electrically coupled to the second section 3111_{C2} of the third substrate 310_{C} and the first section 3111_{D1} of the fourth substrate 310_{D}, wherein the additional first supply terminal 1, the additional second supply terminal 4, and the one or more additional output terminals 2, 3 are arranged in the third section of the housing 37, and between the first lateral side L1 and the first supply terminal 1, the second supply terminal 4 and the one or more output terminals 2, 3.

That is, the first and second sections 3111_{C1}, 3111_{D1}, 3111_{C2}, 3111_{D2} of the third and fourth substrate 310_{C}, 310_{D} are electrically contacted by individual terminals. An electrical connection may be formed outside of the housing 37, by electrically coupling the first supply terminal 1 to the additional first supply terminal 1, the second supply terminal 4 to the additional second supply terminal 4, and the one or more output terminals 2, 3 to the one or more additional output terminals 2, 3, respectively. There is no internal connection (e.g., by means of bonding wires 33) between, e.g., the first section 3111_{A1} of the first substrate 310_{A}, and the first section 3111_{C1} of the third substrate 310_{C}, or between the second section 3111_{A2} of the first substrate 310_{A}, and the second section 3111_{C2} of the third substrate 310_{C}. Similarly, there is no internal connection (e.g., by means of bonding wires 33) between, e.g., the first section 3111_{B1} of the second substrate 310_{B}, and the first section 3111_{D1} of the fourth substrate 310_{D}, or between the second section 3111_{B2} of the second substrate 310_{B}, and the second section 3111_{D2} of the fourth substrate 310_{D}. Similarly, no additional electrical connections (e.g., bonding wires) are required between the first substrate 310_{A} and the second substrate 310_{B}. Any electrical connections between the first substrate 310_{A} and the second substrate 310_{B} are provided by means of the first supply terminal 1, the second supply terminal 4 and the one or more output terminals 2, 3. The same applies for the third substrate 310_{C} and the fourth substrate 310_{D}.

In the example illustrated in FIG. 4, the third substrate 310_{C} and the fourth substrate 310_{D} do not comprise separate auxiliary and control terminals. The third contact pad 2_{C3} of the third controllable semiconductor element 22_{C} may be electrically coupled to the third section 3111_{A3} of the first substrate 310_{A}, for example, and the third contact pad 2_{D3} of the fourth controllable semiconductor element 22_{D} may be electrically coupled to the third section 3111_{B3} of the second substrate 310_{B}. That is, internal connections (e.g., by means of bonding wires 33) may be provided in order to electrically couple the third 310_{C} and the fourth substrate 310_{D} to the respective auxiliary and control terminals provided on the first substrate 310_{A} and the second substrate 310_{B}, respectively. In FIG. 4, electrical connections electrically coupling the third 310_{C} and the fourth substrate 310_{D} to the auxiliary terminals 7, 8, 9, 10 on the first substrate 310_{A} and the second substrate 310_{B}, respectively, are not explicitly illustrated for the sake of clarity. Referring to FIG. 5, however, it is alternatively possible that the third substrate 310_{C} and the fourth substrate 310_{D} do comprise separate control terminals as well as separate auxiliary terminals. That is, the third substrate 310_{C} may be (essentially) identical to the first substrate 310_{A}, and the fourth substrate 310_{D} may be (essentially) identical to the second substrate 310_{B}. This is also schematically illustrated in FIG. 16, for example.

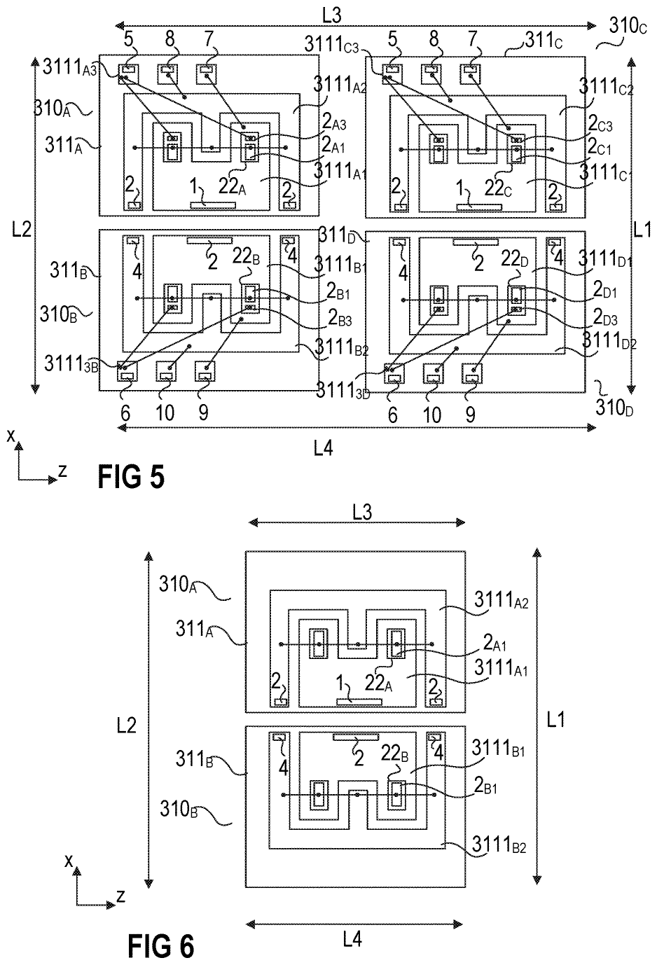

The half-bridge arrangements as illustrated, e.g., in FIGS. 2, 3 to 5, and 7 to 9, however, are only some of a plurality of examples. According to alternative embodiments, passive semiconductor elements such as, e.g., diodes, may be used instead of controllable semiconductor elements. This is schematically illustrated in FIG. 6. That is, according to some embodiments, a semiconductor module arrangement 300 comprises a housing 37 comprising a first lateral side L1, a second lateral side L2 opposite the first lateral side L1, a third lateral side L3 perpendicular to the first lateral side L1 and the second lateral side L2, and a fourth lateral side L4 opposite the third lateral side L3. The semiconductor module arrangement 300 further comprises a first substrate 310_{A} and a second substrate 310_{B} arranged in the housing 37 such that the first substrate 310_{A} is arranged between the second substrate 310_{B} and the third lateral side L3, each of the first and second substrate 310_{A}, 310_{B} comprising a dielectric insulation layer 311_{A}, 311_{B} and a first metallization layer 3111_{A}, 3111_{B} arranged on a surface of the dielectric insulation layer 311_{A}, 311_{B}, wherein the first metallization layer 3111_{A}, 3111_{B} comprises a first section 3111_{A1}, 3111_{B1}, and a second section 3111_{A2}, 3111_{B2}. The semiconductor module arrangement 300 further comprises a first semiconductor element 22_{A} arranged on the first substrate 310_{A}, and a second semiconductor element 22_{B} arranged on the second substrate 310_{B}, wherein each of the first and second semiconductor element 22_{A}, 22_{B} comprises a first contact pad 2x₁, and a second contact pad. The second contact pad of the first semiconductor element 22_{A} is electrically coupled to the first section 3111_{A1} of the first substrate 310_{A}, and the second contact pad of the second semiconductor element 22_{B} is electrically coupled to the first section 3111_{B1} of the second substrate 310_{B}. The first contact pad 2_{A1} of the first semiconductor element 22_{A} is electrically coupled to the second section 3111_{A2} of the first substrate 310_{A}, and the first contact pad 2_{B1} of the second semiconductor element 22_{B} is electrically coupled to the second section 3111_{B2} of the second substrate 310_{B}. The semiconductor module arrangement 300 further comprises a first supply terminal 1 electrically coupled to the first section 3111_{A1} of the first substrate 310_{A}, a second supply terminal 4 electrically coupled to the second section 3111_{B2} of the second substrate 310_{B}, and one or more output terminals 2, 3 electrically coupled to the second section 3111_{A2} of the first substrate 310_{A} and the first section 3111_{B1} of the second substrate 310_{B}, wherein the first supply terminal 1, the second supply terminal 4, and the one or more output terminals 2, 3 are arranged in a third section of the housing 37 arranged between the third lateral side L3 and the fourth lateral side L4, wherein a distance between the third section of the housing 37 and the third lateral side L3 essentially equals a distance between the third section of the housing 37 and the fourth lateral side.

When passive semiconductor elements such as, e.g., diodes, are used instead of controllable semiconductor elements, generally no auxiliary terminal are needed. Therefore, in such cases, an arrangement may only comprise the main terminals. A semiconductor substrate 310 in this case does not necessarily have to comprise a third section 3111₃ of the first metallization layer 3111. However, it is generally also possible that the substrates 310 are implemented in the same way, irrespective of whether passive semiconductor components or controllable semiconductor elements are arranged thereon. If a passive semiconductor component is arranged on a substrate 310 comprising a third section 3111₃, the third section 3111₃ may simply not be electrically contacted, for example. Similarly, other sections, elements, or terminals may not be electrically contacted, even if they are provided on a substrate 310 by default. It is generally possible to combine one or more arrangements as described with respect to FIG. 3 with one or more arrangements as described with respect to FIG. 6 in a single housing 37, for example.

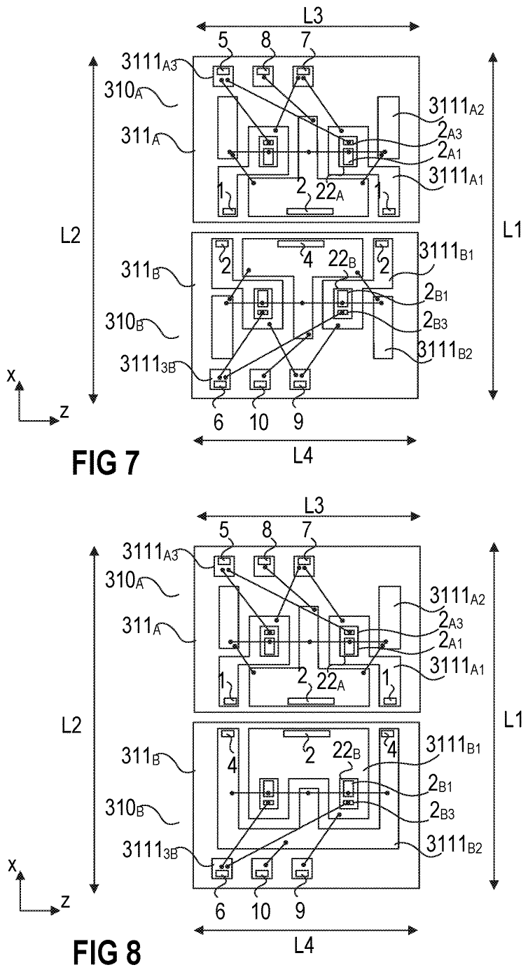

The arrangements as illustrated in FIGS. 3 and 6 are highly symmetrical. In these examples, the first substrate 310_{A} and the second substrate 310_{B}, in particular the first and second sections 3111_{A1}, 3111_{A2}, 3111_{B1}, 3111_{B2} of the respective first metallization layers, are implemented in an (almost) symmetric way. The specific shape and arrangement of the first and second sections 3111_{A1}, 3111_{A2}, 3111_{B1}, 3111_{B2} as illustrated in FIGS. 3 and 6, however, is only one out of several possible implementations. Referring to FIG. 7, another possible implementation of the first and second sections 3111_{A1}, 3111_{A2}, 3111_{B1}, 3111_{B2} is schematically illustrated. It is noted that a section of the first metallization layer 3111ₓ may be formed by a single continuous section. This is the case, for example, for the first and second sections 3111_{A1}, 3111_{B1}, 3111_{A2}, 3111_{B2} in the examples illustrated in FIGS. 3, 4, 5 and 6, for example. It is, however, also possible that a section of the first metallization layer 3111ₓ is formed by two or more separate sections that are, however, electrically coupled to each other by means of one or more electrical connection elements such as, e.g., bonding wires, bonding ribbons, connection plates or conductor rails. This is the case, for example, for the second sections 3111_{A2}, 3111_{B2} in the example illustrated in FIG. 7. Many other different implementations (e.g., shapes, arrangements, etc.) are generally possible. In the examples illustrated in FIGS. 3, 6, and 7, the first substrate 310_{A} and the second substrate 310_{B} are identical to a high degree. According to some examples, the first substrate 310_{A} and the second substrate 310_{B} may be essentially symmetrical with respect to an axis of symmetry extending between the first substrate 310_{A} and the second substrate 310_{B} and in parallel to the third and fourth longitudinal sides L3, L4.

It is, however, not necessarily required that the first substrate 310_{A} and the second substrate 310_{B} are symmetrical to each other. Referring to FIG. 8, it is also possible that the first substrate 310_{A} and the second substrate 310_{B} are implemented in different ways. In the embodiment illustrated in FIG. 8, for example, the first substrate 310_{A} is implemented according to the example of FIG. 3, while the second substrate 310_{B} is implemented according to the example of FIG. 7. Each of the first substrate 310_{A} and the second substrate 310_{B}, however, may be implemented in any other suitable way.

According to some embodiments, at least one portion of the first section 3111_{A1} and the second section 3111_{A2} of the first substrate 310_{A} may extend along a side of the first substrate 310_{A} facing towards the second substrate 310_{B}. Similarly, at least one portion of the first section 3111_{B1} and the second section 3111_{B2} of the second substrate 310_{B} may extend along a side of the second substrate 310_{B} facing towards the first substrate 310_{A}. This allows arranging the first supply terminal 1, the second supply terminal 4 and the one or more output terminals 2, 3 centrally between the third longitudinal side L3 and the fourth longitudinal side L4.

Now referring to FIG. 10, a top view of a semiconductor module arrangement according to even further embodiments of the disclosure is schematically illustrated. In this example, the semiconductor module arrangement comprises the first, second, third and fourth substrates as described above, as well as additional fifth and sixth substrates. The first metallization layers as well as the (controllable) semiconductor elements are not specifically illustrated in the figure for the sake of clarity. Electrical connections between the different substrates (e.g., for electrically connecting the different substrates to the auxiliary and control terminals provided on the first substrate and the second substrate, respectively) are only schematically illustrated in FIG. 10. As has been described above, no electrical connections are provided between the different substrates with respect to the main terminals. That is, individual first supply terminals 1, second supply terminals 4 and output terminals 2, 3 are provided for each pair of substrates. As has been described above, the first and second substrate form a pair of substrates, and the third and fourth substrate form a pair of substrates. Similarly, the fifth and sixth substrate form a pair of substrates.

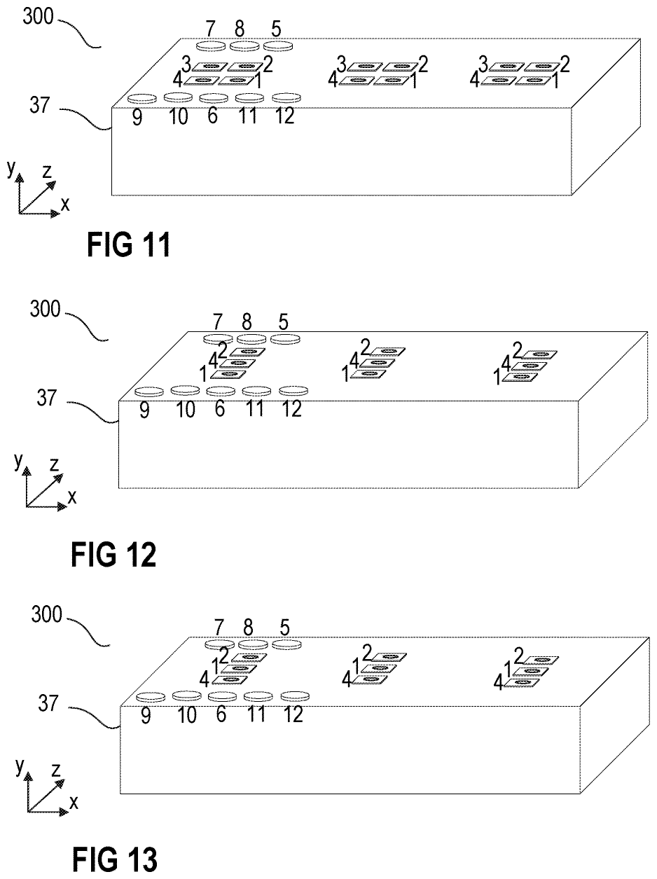

FIG. 11 schematically illustrates a three-dimensional view of a housing 37 of a semiconductor module arrangement according to some embodiments of the disclosure. As has been described above and as is schematically illustrated in FIG. 11, the semiconductor module arrangement may comprise two output terminals 2, 3, wherein a second end of the first supply terminal 1 arranged outside of the housing 37, and a second end of the second supply terminal 4 arranged outside of the housing 37 are arranged in one row and in parallel to the third and fourth lateral sides L3, L4, second ends of the two output terminals 2, 3 arranged outside of the housing 37 are arranged in one row and in parallel to the third and fourth lateral sides L3, L4, and the second end of the first supply terminal 1 and the second end of the second supply terminal 4 are arranged between the second ends of the two output terminals 2, 3 and the fourth lateral side L4. This arrangement of the second ends of the respective main terminals may be the same for each pair of substrates included in the semiconductor module arrangement.

As mentioned above, according to alternative embodiments, the semiconductor module arrangement may comprise only one output terminal 2, wherein a second end of the first supply terminal 1 arranged outside of the housing 37, a second end of the second supply terminal 4 arranged outside of the housing 37, and a second end of the output terminal 2 arranged outside of the housing 37 are arranged in one row and in parallel to the first and second lateral sides L1, L2

FIG. 12 schematically illustrates a three-dimensional view of a housing of a semiconductor module arrangement according to further embodiments of the disclosure. In this embodiment, the second end of the second supply terminal 4 may be arranged between the second end of the output terminal 2 and the second end of the first supply terminal 1. This arrangement of the second ends of the respective main terminals may be the same for each pair of substrates included in the semiconductor module arrangement. FIG. 13 schematically illustrates a three-dimensional view of a housing of a semiconductor module arrangement according to even further embodiments of the disclosure. In this embodiment, the second end of the first supply terminal 1 may be arranged between the second end of the second supply terminal 4 and the second end of the output terminal 2. This arrangement of the second ends of the respective main terminals may be the same for each pair of substrates included in the semiconductor module arrangement. FIG. 14 schematically illustrates a three-dimensional view of a housing of a semiconductor module arrangement according to even further embodiments of the disclosure. In this embodiment, the second end of the output terminal 2 may be arranged between the second end of the first supply terminal 1 and the second end of the second supply terminal 4. This arrangement of the second ends of the respective main terminals may be the same for each pair of substrates included in the semiconductor module arrangement.

FIG. 15 schematically illustrates a three-dimensional view of a housing 37 of a semiconductor module arrangement according to an even further embodiment of the disclosure. In this embodiment, all auxiliary terminals are arranged in one and the same row along the third longitudinal side L3 of the housing 37. FIG. 16 schematically illustrates a three-dimensional view of a housing 37 of a semiconductor module arrangement according to an even further embodiment of the disclosure. In this embodiment, auxiliary terminals are provided for each pair of substrates, similar to what has been described with respect to FIG. 5.

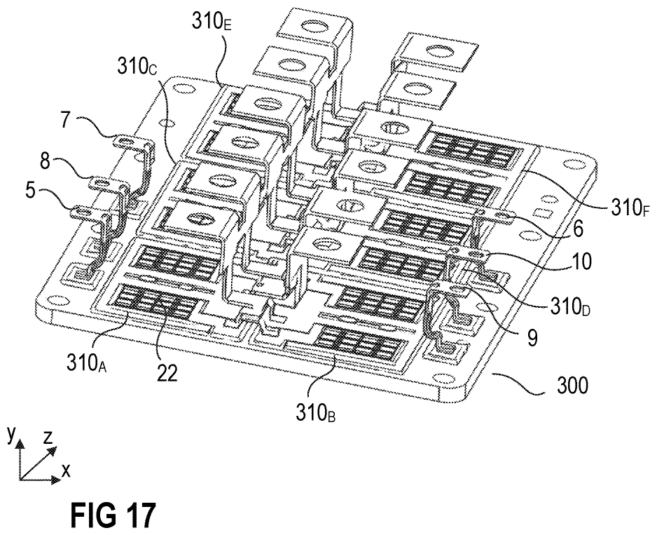

FIG. 17 schematically illustrates a three-dimensional view of a semiconductor module arrangement according to even further embodiments of the disclosure. In this example, possible implementations of the different terminals are schematically illustrated. The different substrates as well as the different sections of the respective first metallization layers and the controllable semiconductor elements are visible in FIG. 17. No bonding wires or other internal electrical connections are illustrated in FIG. 17 for the sake of clarity.

The semiconductor module arrangements according to the various embodiments described herein fulfill a plurality of different requirements. For example, the semiconductor module arrangement according to the various examples described herein has a comparably low stray inductance. For example, the stray inductance is reduced by arranging the one or more output terminals 2, 3 as well as the first supply terminal 1 and the second supply terminal 2 centrally between the third longitudinal side L3 and the fourth longitudinal side L4. Further, a highly symmetric switching behavior between low side and high side can be achieved by means of the semiconductor module arrangements described herein. The overall losses in the semiconductor module arrangement described herein are also comparably low.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor module arrangement, comprising:
a housing comprising a first lateral side, a second lateral side opposite the first lateral side, a third lateral side perpendicular to the first lateral side and the second lateral side, and a fourth lateral side opposite the third lateral side;
a first substrate and a second substrate arranged in the housing such that the first substrate is arranged between the second substrate and the third lateral side, each of the first and second substrate comprising a dielectric insulation layer and a first metallization layer arranged on a surface of the dielectric insulation layer, wherein the first metallization layer comprises a first section and a second section; and
a first semiconductor element arranged on the first substrate and a second semiconductor element arranged on the second substrate, wherein each of the first and second semiconductor element comprises a first contact pad and a second contact pad,
wherein the second contact pad of the first semiconductor element is electrically coupled to the first section of the first substrate,
wherein the second contact pad of the second semiconductor element is electrically coupled to the first section of the second substrate,
wherein the first contact pad of the first semiconductor element is electrically coupled to the second section of the first substrate,
wherein the first contact pad of the second semiconductor element is electrically coupled to the second section of the second substrate,
wherein the semiconductor module arrangement further comprises:
a first supply terminal electrically coupled to the first section of the first substrate;
a second supply terminal electrically coupled to the second section of the second substrate; and
one or more output terminals electrically coupled to the second section of the first substrate and the first section of the second substrate,
wherein the first supply terminal, the second supply terminal and the one or more output terminals are arranged in a third section of the housing arranged between the third lateral side and the fourth lateral side,
wherein a distance between the third section of the housing and the third lateral side essentially equals a distance between the third section of the housing and the fourth lateral side.

2. The semiconductor module arrangement of claim 1, wherein:
the first metallization layer of each of the first substrate and the second substrate further comprises a third section;
the first semiconductor element is a controllable semiconductor element and further comprises a third contact pad;
the second semiconductor element is a controllable semiconductor element and further comprises a third contact pad;
the third contact pad of the first controllable semiconductor element is electrically coupled to the third section of the first substrate;
the third contact pad of the second controllable semiconductor element is electrically coupled to the third section of the second substrate; and
the semiconductor module arrangement further comprises:
a first control terminal electrically coupled to the third section of the first substrate, a first auxiliary emitter terminal electrically coupled to the second section of the first substrate, and a first collector terminal electrically coupled to the first section of the first substrate, wherein the first control terminal, the first auxiliary emitter terminal, and the first collector terminal are arranged in a first section of the housing between the third section and the third lateral side;
a second control terminal electrically coupled to the third section of the second substrate, a second auxiliary emitter terminal electrically coupled to the second section of the second substrate, and a second collector terminal electrically coupled to the first section of the second substrate, wherein the second control terminal, the second auxiliary emitter terminal, and the second collector terminal are arranged in the first section of the housing or in a second section of the housing between the third section and the fourth lateral side.

3. The semiconductor module arrangement of claim 2, wherein the first control terminal, the first auxiliary emitter terminal and the first collector terminal are arranged in one row and in parallel to the third lateral side.

4. The semiconductor module arrangement of claim 2, wherein the second control terminal, the second auxiliary emitter terminal and the second collector terminal are arranged in one row and in parallel to the fourth lateral side.

5. The semiconductor module arrangement of claim 1, wherein:
the semiconductor module arrangement comprises two output terminals;
a second end of the first supply terminal arranged outside of the housing and a second end of the second supply terminal arranged outside of the housing are arranged in one row and in parallel to the third and fourth lateral sides;
second ends of the two output terminals arranged outside of the housing are arranged in one row and in parallel to the third and fourth lateral sides; and
the second end of the first supply terminal and the second end of the second supply terminal are arranged between the second ends of the two output terminals and the fourth lateral side.

6. The semiconductor module arrangement of claim 1, wherein the semiconductor module arrangement comprises one output terminal, and wherein a second end of the first supply terminal arranged outside of the housing, a second end of the second supply terminal arranged outside of the housing and a second end of the output terminal arranged outside of the housing are arranged in one row and in parallel to the first and second lateral sides.

7. The semiconductor module arrangement of claim 6, wherein the second end of the second supply terminal is arranged between the second end of the output terminal and the second end of the first supply terminal.

8. The semiconductor module arrangement of claim 6, wherein the second end of the first supply terminal is arranged between the second end of the second supply terminal and the second end of the output terminal.

9. The semiconductor module arrangement of claim 6, wherein the second end of the output terminal is arranged between the second end of the first supply terminal and the second end of the second supply terminal.

10. The semiconductor module arrangement of claim 1, further comprising:
a third substrate and a fourth substrate arranged in the housing such that the third substrate is arranged between the fourth substrate and the third lateral side and between the first substrate and the first lateral side, and the fourth substrate is arranged between the second substrate and the first lateral side, each of the third and fourth substrate comprising a dielectric insulation layer and a first metallization layer arranged on a surface of the dielectric insulation layer, wherein the first metallization layer comprises a first section and a second section; and
a third semiconductor element arranged on the third substrate and a fourth semiconductor element arranged on the fourth substrate, wherein each of the third and fourth controllable semiconductor element comprises a first contact pad and a second contact pad,
wherein the second contact pad of the third semiconductor element is electrically coupled to the first section of the third substrate and the second contact pad of the fourth semiconductor element is electrically coupled to the first section of the fourth substrate,
wherein the first contact pad of the third semiconductor element is electrically coupled to the second section of the third substrate and the first contact pad of the fourth semiconductor element is electrically coupled to the second section of the fourth substrate,
wherein the semiconductor module arrangement further comprises an additional first supply terminal electrically coupled to the first section of the third substrate, an additional second supply terminal electrically coupled to the second section of the fourth substrate, and one or more additional output terminals electrically coupled to the second section of the third substrate and the first section of the fourth substrate,
wherein the additional first supply terminal, the additional second supply terminal and the one or more additional output terminals are arranged in the third section of the housing, and between the first lateral side and the first supply terminal, the second supply terminal and the one or more output terminals.

11. The semiconductor module arrangement of claim 10, wherein:
the third semiconductor element is a controllable semiconductor element and further comprises a third contact pad;
the fourth semiconductor element is a controllable semiconductor element and further comprises a third contact pad;
the third contact pad of the third controllable semiconductor element is electrically coupled to the third section of the first substrate; and
the third contact pad of the fourth controllable semiconductor element is electrically coupled to the third section of the second substrate.

12. The semiconductor module arrangement of claim 1, wherein each of the first and second semiconductor elements comprises at least one diode, at least one IGBT, at least one MOSFET, at least one JFET, or at least one HEMT.
